(19) United States
(12) Patent Application Publication
(10) Pub. No.: US 2008/0265760 A1
(43) Pub. Date: Oct. 30, 2008

(54) ORGANIC LIGHT-EMITTING DISPLAY DEVICE

(75) Inventors: Sukekazu Aratani, Hitachiota (JP); Yasushi Tomioka, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi, Ltd.

(21) Appl. No.: 12/108,540

(22) Filed: Apr. 24, 2008

(30) Foreign Application Priority Data
Apr. 25, 2007 (JP) 2007-116004

(51) Int. Cl. H01J 1/62; H01L 51/52; H01J 9/02; B05D 7/00

(52) U.S. Cl. 313/504; 445/24; 427/58

(57) ABSTRACT

It is an object of the present invention to provide an organic light-emitting display device which can be simply produced by a wet process, and exhibit a high efficiency and long serviceability. The present invention provides an organic light-emitting display device having an organic light-emitting layer 3 placed between an upper electrode 5 and a lower electrode 1, one of the upper electrode 5 and the lower electrode 1 is transparent electrode and the other is a light-reflecting electrode, wherein the organic light-emitting layer 3 contains a binder, hole transport material, electron transport material and light-emitting dopant.

### FIELD OF THE INVENTION

The present invention relates to an organic light-emitting display device (organic light-emitting element).

### BACKGROUND OF THE INVENTION

Recently, organic light-emitting display devices have been attracting attention as planar display devices of the next generation. They exhibit excellent characteristics, e.g., workability with natural light, wide viewing angle and high responsiveness.

An organic light-emitting display device is generally composed of a glass substrate which supports a transparent electrode (e.g., ITO electrode), various organic layers, e.g., hole transport layer, light-emitting layer and electron transport layer, and a light-reflecting electrode of low work function. Light is emitted from the back side of the substrate after being transmitted by the electrode.

The organic light-emitting display device of the above structure has been improved in efficiency and serviceability, realized by forming these organic layers by vacuum deposition. For example, R. Meertheim et. al. discuss that an organic, red light emitting display device can be produced by vacuum deposition to have a brightness half-life of 1,500,000 hours or more when it has an initial brightness of 500 cd/m² (as disclosed in Non-patent document 1).

Some of the techniques to produce organic layers for an organic light-emitting display device without using vacuum deposition include spin coating and ink jetting. The devices produced by these wet processes are inferior in serviceability and efficiency to those produced by vacuum deposition. For example, an organic, red light emitting display device produced by spin coating with a polymer material is serviceable for about 100,000 hours when it has an initial brightness of 500 cd/m² (as disclosed in Non-patent Document 2).

If a printing method, e.g., ink jetting, can form an organic layer, it can produce an organic light-emitting display device more simply, because it can dispense with metal masks needed by vacuum deposition. Non-patent Document 3, for example, discloses performance of a device whose light-emitting layer is formed by a wet process with a so-called low-molecular-weight material, which is used by vacuum deposition, after being dispersed in a high-molecular-weight material (polyvinyl carbazole). Patent Document 1 discusses production of an organic light-emitting display device of improved performance by a wet process, with a light-emitting layer of high-molecular-weight materials each having a light-emitting host site, hole transport site or electron transport site, and containing a phosphorescent dopant.

(Non-patent Document 1) Appl. Phys. Lett., 89, 061111 (2006)

### (Non-patent Document 2) IDW '06, p. 441 (2006)

(Non-patent Document 3) Appl. Phys. Lett., 77, 2280 (2000)

### (Patent Document 1): JP-A-2004-185967

### BRIEF SUMMARY OF THE INVENTION

A light-emitting layer can be certainly formed by a wet process using a low-molecular-weight material when it has the structure disclosed by Non-patent document 3. However, it has an insufficient efficiency, roughly one-tenth of that of a layer produced by vacuum deposition, conceivably resulting from deteriorated charge balance due to lack of electron transport material and increased leak paths due to agglomeration and crystallization of the light-emitting layer.

A light-emitting display device can be also produced by a wet process using a low-molecular-weight material when it has the structure disclosed by Patent Document 1. However, it fails to exhibit a sufficient efficiency and serviceability, conceivably resulting from use of a functional high-molecular-weight material having a plurality of functions, e.g., light-emitting host site and hole transport site, which tends to crystallize the light-emitting layer and increase leak paths.

It is an object of the present invention to provide an organic light-emitting display device which can be simply produced by a wet process, and exhibit a high efficiency and long serviceability.

The aspects of the present invention developed to achieve the above object are summarized below.

(1) An organic light-emitting display device comprising:

an upper electrode;

a lower electrode; and

an organic light-emitting layer placed between the upper electrode and the lower electrode, wherein one of the upper and lower electrodes is a transparent electrode and the other is a light-reflecting electrode, and

wherein the organic light-emitting layer contains at least one of a hole transport material and an electron transport material and contains a light-emitting dopant.

(2) The organic light-emitting display device according to the above aspect (1), wherein the organic light-emitting layer contains the hole transport material and the electron transport material, and each of the hole transport material, the electron transport material and the light-emitting dopant in the organic light-emitting layer has a molecular structure not point-symmetric.
(3) The organic light-emitting display device according to the above aspect (1), wherein the organic light-emitting layer contains the electron transport material, and each of the electron transport material and the light-emitting dopant in the organic light-emitting layer has a molecular structure not point-symmetric.
(4) The organic light-emitting display device according to the above aspect (1), wherein the organic light-emitting layer contains the hole transport material, and each of the hole transport material and the light-emitting dopant in the organic light-emitting layer has a molecular structure not point-symmetric.
(5) The organic light-emitting display device according to the above aspect (1), wherein the organic light-emitting layer contains a binder, the hole transport material, the electron transport material and the light-emitting dopant.
(6) The organic light-emitting display device according to the above aspect (1), wherein the organic light-emitting layer contains a hole transport binder, the electron transport material and the light-emitting dopant.
(7) The organic light-emitting display device according to the above aspect (1), wherein the organic light-emitting layer contains an electron transport binder, the hole transport material and the light-emitting dopant.
(8) The organic light-emitting display device according to the above aspect (1), wherein the organic light-emitting layer contains a binder, a hole/electron transport material and the light-emitting dopant.
(9) The organic light-emitting display device according to the above aspect (1), further comprising an organic layer in contact with the upper electrode or the lower electrode, wherein the organic layer contains a dopant capable of ionizing a material present in the organic layer.
(10) The organic light-emitting display device according to the above aspect (5), wherein at least one of the binder, the hole transport material, the electron transport material and the light-emitting dopant has a molecular structure not point-symmetric.
(11) The organic light-emitting display device according to the above aspect (6), wherein at least one of the hole transport binder, the electron transport material and the light-emitting dopant has a molecular structure not point-symmetric.
(12) The organic light-emitting display device according to the above aspect (7), wherein at least one of the electron transport binder, the hole transport material and the light-emitting dopant has a molecular structure not point-symmetric.
(13) The organic light-emitting display device according to the above aspect (8), wherein at least one of the binder, the hole/electron transport material and the light-emitting dopant has a molecular structure not point-symmetric.
(14) The organic light-emitting display device according to the above aspect (10), wherein the light-emitting dopant is a metallic complex having at least two species of ligands.
(15) The organic light-emitting display device according to the above aspect (11), wherein the light-emitting dopant is a metallic complex having at least two species of ligands.
(16) The organic light-emitting display device according to the above aspect (12), wherein the light-emitting dopant is a metallic complex having at least two species of ligands.
(17) The organic light-emitting display device according to the above aspect (13), wherein the light-emitting dopant is a metallic complex having at least two species of ligands.
(18) The organic light-emitting display device according to the above aspect (10), wherein the hole transport material has a structure represented by the following general formula:

A-B-C (formula 1)

(wherein, A and C are each an aryl group which can be substituted, and B is a coupling group or mere bond which couples A and C with each other), or by the following general formula:

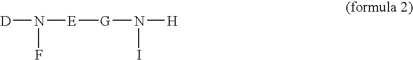

(wherein, D, E, F, G, H and I are each an aryl group which can be substituted, and at least one of D, E and F is not the same as the another and at least one of G, H and I is not the same as the another).
(19) The organic light-emitting display device according to the above aspect (12), wherein the hole transport material has a structure represented by the following general formula:

A-B-C (formula 1)

(wherein, A and C are each an aryl group which can be substituted, and B is a coupling group or mere bond which couples A and C with each other), or by the following general formula:

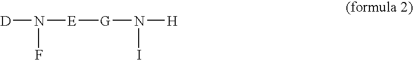

(wherein, D, E, F, G, H and I are each an aryl group which can be substituted, and at least one of D, E and F is not the same as the another and at least one of G, H and I is not the same as the another).
(20) The organic light-emitting display device according the above aspect (10), wherein the electron transport material has a structure represented by the following general formula:

J-K-L (formula 3)

(wherein, J and L are each an aryl group which can be substituted, and K is a coupling group or mere bond which couples J and L with each other), or by the following general formula:

M-N-O (formula 4)

(wherein, M and O are each an aryl group which can be substituted, and N is a coupling group or mere bond which couples J and L with each other).
(21) The organic light-emitting display device according the above aspect (11), wherein the electron transport material has a structure represented by the following general formula:

J-K-L (formula 3)

(wherein, J and L are each an aryl group which can be substituted, and K is a coupling group or mere bond which couples J and L with each other), or by the following general formula:

M-N-O (formula 4)

(wherein, M and O are each an aryl group which may be substituted, and N is a coupling group or mere bond which couples J and L with each other).
(22) The organic light-emitting display device according to the above aspect (1), wherein the organic light-emitting layer contains a surfactant.
(23) The organic light-emitting display device according to the above aspect (1), wherein the organic light-emitting layer contains the hole transport material and the electron transport material.
(24) A coating solution for producing an organic light-emitting layer in an organic light-emitting display device, wherein the organic light-emitting layer is placed between an upper electrode and a lower electrode in the device and the coating solution contains a binder, at least one of a hole transport material and an electron transport material, and a light-emitting dopant and a solvent.
(25) The coating solution for producing an organic light-emitting layer according to the above aspect (24), wherein the coating solution contains a hole transport binder, the electron transport material, the light-emitting dopant and the solvent.
(26) The coating solution for producing an organic light-emitting layer according to the above aspect (24), wherein the coating solution contains an electron transport binder, the hole transport material, the light-emitting dopant and the solvent.
(27) The coating solution for producing an organic light-emitting layer according to the above aspect (24), wherein the coating solution contains the binder, a hole/electron transport material, the light-emitting dopant and the solvent.
(28) The coating solution for producing an organic light-emitting layer according to the above aspect (24), further comprising a surfactant.

Other objects, features and advantages of the invention will become apparent from the following description of the embodiments of the invention taken in conjunction with the accompanying drawings.

### BRIEF DESCRIPTION OF THE DRAWINGS

FIG. 1 is a cross-sectional view illustrating the first embodiment of organic light-emitting display device of the present invention.

FIG. 2 is a cross-sectional view illustrating the second embodiment of organic light-emitting display device of the present invention.

FIG. 3 is a cross-sectional view illustrating the third embodiment of organic light-emitting display device of the present invention.

FIG. 4 is a cross-sectional view illustrating the fourth embodiment of organic light-emitting display device of the present invention.

FIG. 5 is a cross-sectional view illustrating the fifth embodiment of organic light-emitting display device of the present invention.

FIG. 6 is a cross-sectional view illustrating the sixth embodiment of organic light-emitting display device of the present invention.

FIG. 7 is a cross-sectional view illustrating the seventh embodiment of organic light-emitting display device of the present invention.

### DESCRIPTION OF REFERENCE NUMERALS

1 Lower electrode
2 Hole-injecting layer
3 Organic light-emitting layer
4 Electron transport layer
5 Upper electrode
6 electron-injecting layer
7 Organic light-emitting layer
8 Organic light-emitting layer
9 Organic light-emitting layer
10 Lower electrode
11 Hole-injecting layer
12 Organic light-emitting layer
13 Electron transport layer
14 Buffer layer
15 Upper electrode
16 Lower electrode
17 Electron transport layer
18 Organic light-emitting layer
19 Hole transport layer
20 Buffer layer
21 Upper electrode

### DETAILED DESCRIPTION OF THE INVENTION

The present invention is described in detail by the embodiments.

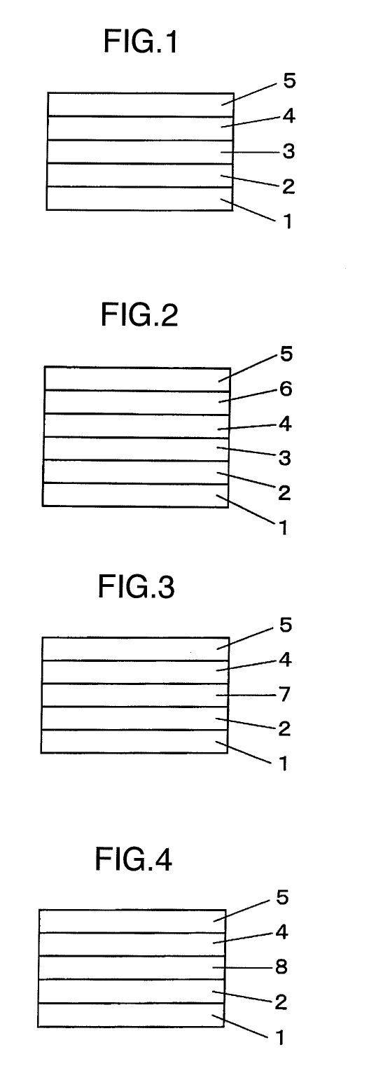

FIG. 1 is a cross-sectional view illustrating the first embodiment of organic light-emitting display device of the present invention. It has an organic light-emitting layer 3 placed between an upper electrode 5 and lower electrode 1. More specifically, it has a structure with a lower electrode 1, hole-injecting layer 2, organic light-emitting layer 3, electron transport layer 4 and upper electrode 5, in this order. It is of bottom emission type which emits light produced in the organic light-emitting layer from the lower electrode side, wherein the lower electrode 1 is a transparent electrode serving as an anode and the upper electrode is a light-reflecting electrode serving as a cathode.

The anode material for the lower electrode 1 is not limited so long as it is transparent and has a high work function. The useful materials include electroconductive oxides, e.g., ITO and IZO, and a metal having a high work function such as thin Ag. Electrode patterns may be generally formed on a substrate, e.g., glass, by photolithography.

The suitable materials for the hole-injecting layer 2 include electroconductive high-molecular-weight compounds (polymers), e.g., poly(3,4-ethylenedioxythiophene) (PEDOT) and polystyrene sulfonate (PSS). The other useful materials include polymers, e.g., polypyrrole- and triphenylamine-base ones. Moreover, phthalocyanine-base compounds and star-burst amine-base compounds, which are frequently used in combination with a low-molecular-weight compound, may be used. The hole-injecting layer 2 may have a stacked structure with another layer capable of transferring holes and blocking electrons.

In the first embodiment, the organic light-emitting layer 3 is characterized in that it contains a binder, hole transport material, electron transport material and light-emitting dopant. The binder material is not limited so long as it can uniformly disperse a light-emitting dopant. The suitable materials include polycarbonate represented by the formula [b-1]. The other useful materials include polystyrene, polyester, polyalkyl methacrylate and polysulfone. They may be used either individually or in combination. The binder particularly preferably has a molecular structure not point-symmetric, which means that the structure (or repeating unit structure in the case of binder), when rotated by 180 degrees, does not lap over the original structure. Such a molecular structure can prevent crystallization in the light-emitting layer caused by agglomeration, and can reduce leak paths. Use of a binder of the above structure can give a light-emitting layer uniformly dispersed with a light-emitting dopant, and hence an organic light-emitting device of high efficiency and long serviceability by a simple wet process.

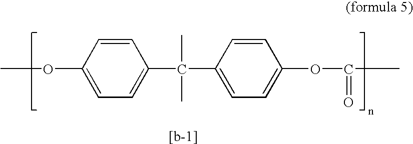

The useful materials for the hole transport layer include, but not limited to, star-burst amine-base compounds, stilbene derivatives, hydrazone derivatives and thiophene derivatives. They may be used either individually or in combination.

Of these compounds, those having a molecular structure not point-symmetric are suitably used for their capability of preventing crystallization of the light-emitting layer. More specifically, the hole transport materials having a structure represented by the following general formula are particularly preferable, wherein, A and C are each an aryl group which may be substituted, and B is a coupling group or mere bond which couples A and C with each other. Those represented by the general formula include N,N′-diphenyl-N,N′-di(m-tolyl)-benzidine. The aryl group used in this specification is not limited to aromatic hydrocarbons composed of C and H atoms, but includes heteroaryl groups with a hetero atom, e.g., N, in the ring.

A-B-C (formula 6)

Moreover, those hole transport materials represented by the following general formula are also preferably used, wherein, D, E, F, G, H and I are each an aryl group which may be substituted, at least one of D, E and F being not the same as the another, and at least one of G, H and I being not the same as the another.

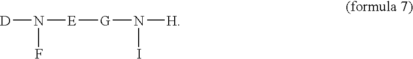

Examples of the hole transport materials having the above structure include, but not limited to, triphenyl derivatives represented by the structures [h-1] to [h-3].

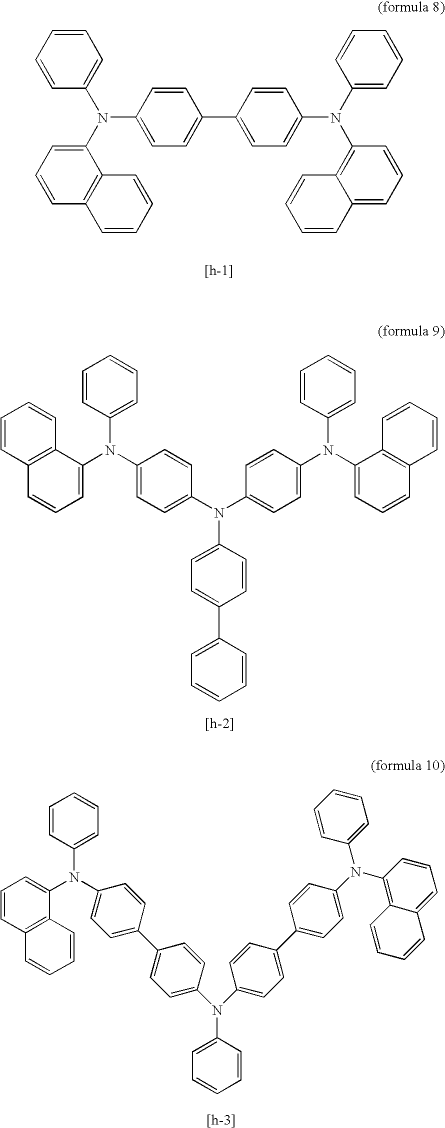

The electron transport materials include carbazole derivatives, oxadiazole derivatives, oxathiazole derivatives, triazole derivatives, fullerene derivatives, phenanthroline derivatives and quinoline derivatives. They may be used either individually or in combination. Of these compounds, those having a molecular structure not point-symmetric are suitably used for their capability of preventing crystallization of the light-emitting layer. Moreover, the electron transport materials having a structure represented by the following general formula are suitably used, wherein J and L are each an aryl group which may be substituted, and K is a coupling group or mere bond which couples J and L with each other. Examples of these materials include 2-(4-biphenyl)-5-(4-tert-butylphenyl)-1,3,4-oxadiazole.

J-K-L (formula 11)

The electron transport materials particularly preferably used for the present invention include, but not limited to, carbazole derivatives represented by the structure [e-1] and those represented by the structure [e-2].

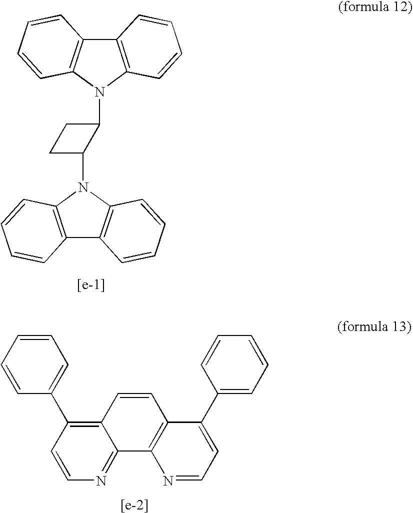

The light-emitting dopants include phosphorescence-emitting materials, e.g., Ir complexes, Pt complexes and Os complexes. The other useful dopants include so-called fluorescence-emitting materials, e.g., distyrylallylene derivatives, coumarine derivatives and quinacridone derivatives. More specifically, they include Ir complexes represented by the structure [d-1].

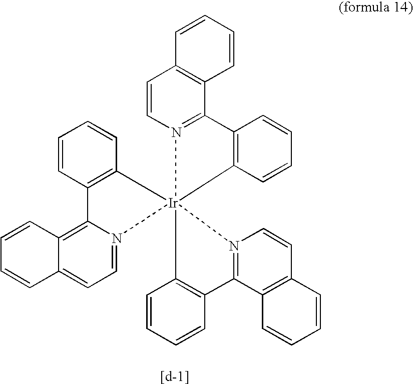

Moreover, the light-emitting dopants having a molecular structure not point-symmetric are suitably used. Of these compounds, metallic complexes having at least two species of ligands are particularly preferably used. Examples of these compounds include those represented by the following structure [d-2]

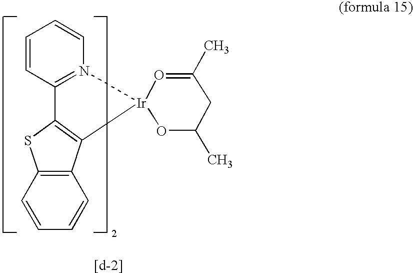

The Ir complex represented by the structure [d-1] or [d-2] is now used as a dopant for a red light emitting device. Dopants can be used for other colors. For example, the dopant represented by the structure [d-3] or [d-4] can be used for green or blue color. The dopant represented by the structure [d-4] is not point-symmetric and can prevent crystallization of the light-emitting layer.

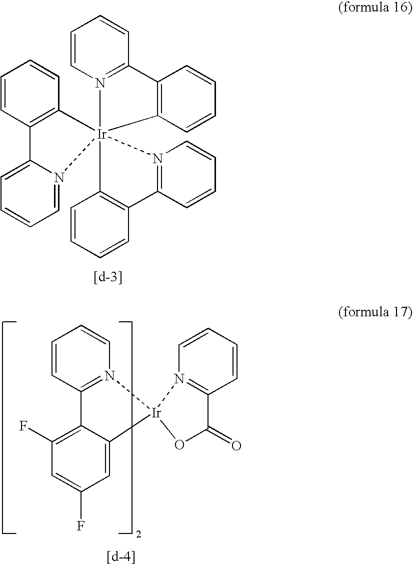

It is preferable that at least one of the binder, hole transport material, electron transport material and light-emitting dopant has a structure not point-symmetric. Particularly preferably, at least two of them have a structure not point-symmetric. The organic light-emitting layer can be produced by a wet process, e.g., ink jetting, printing, spraying or the like, using a coating solution with the above-described binder, hole transport material, electron transport material and light-emitting dopant dissolved in a solvent. The solvent may be a mixture of polar solvents selected from aromatic compounds, alcohols and so forth. The solvent conditions, e.g., composition and solid concentration, can be adequately set depending on desired film thickness and the like. When ink jetting is adopted, for example, it is preferable to adjust coating solution (ink) viscosity at 1 to 20 mPa·s, which however is not essential.

The electron transport layer 4 works to supply electrons to the organic light-emitting layer. The compounds useful for the electron transport layer 4 include bis(2-methyl-8-quinolinolato)-4-(phenylphenolato) aluminum (BAlq), tris(8-quinolinolato) aluminum derivatives, oxadiazole derivatives, triazole derivatives, fullerene derivatives and phenanthroline derivatives.

The upper electrode 5 is a light-reflecting electrode for reflecting light from the light-emitting layer. More specifically, a laminate of LiF and Al can be suitably used for the upper electrode 5. The suitable materials are not limited to the above. For example, LiF may be replaced by a Cs compound, Ba compound or Ca compound. The other suitable materials include an electron transport material codeposited with an alkaline metal (e.g., Li or Cs), alkaline-earth metal, electron-donating organic material or the like.

The organic light-emitting display device thus produced has the light-emitting layer uniformly dispersed with the light-emitting dopant and is prevented from being crystallized to reduce leak paths. As a result, it is highly efficient and serviceable for extended periods of time.

FIG. 2 illustrates the second embodiment of organic light-emitting display device of the present invention. It has an electron-injecting layer 6 as an organic layer in contact with an upper electrode, the layer 6 being placed between an electron transport layer 4 and upper electrode 5. The electron-injecting layer 6 may contain a dopant capable of ionizing a material present in the layer 6. For example, it may be of an electron transport material codeposited with Cs or the like working as a dopant, to improve power efficiency of the device. In a structure other than that illustrated in FIG. 2, an organic layer may be disposed to come into contact with a lower electrode, where the organic layer contains a dopant capable of ionizing a material present in the layer.

FIG. 3 illustrates the third embodiment of organic light-emitting display device of the present invention. In this embodiment, an organic light-emitting layer 7 is characterized in that it contains a hole transport binder, electron transport material and light-emitting dopant. The hole transport binder material is not limited so long as it has a function of transferring holes. Of hole transport binder materials, those having a molecular structure not point-symmetric are suitably used for their capability of preventing crystallization of the light-emitting layer. One example of the hole transport binder has the structure represented by [b-2].

In the third embodiment, the organic light-emitting layer 7 may be produced by a wet process using another electron transport material or the like, another layer configuration, or another coating solution, as is the case with the first embodiment. At least one of the hole transport binder, electron transport material and light-emitting dopant in the light-emitting layer 7 preferably has a molecular structure not point-symmetric. Particularly preferably, at least two of them have a molecular structure not point-symmetric.

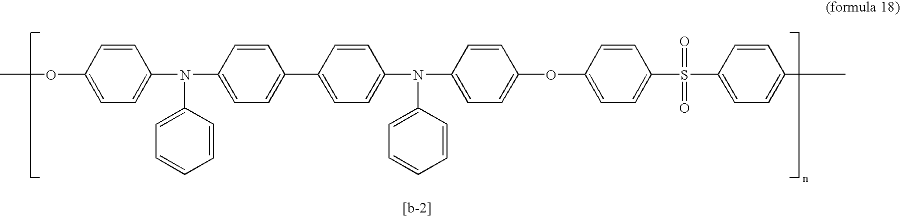

FIG. 4 illustrates the fourth embodiment of organic light-emitting display device of the present invention. In this embodiment, an organic light-emitting layer 8 is characterized in that it contains an electron transport binder, hole transport material and light-emitting dopant. The electron transport binder material is not limited so long as it has a function of transferring electrons. Of electron transport binder materials, those having a molecular structure not point-symmetric are suitably used for their capability of preventing crystallization of the light-emitting layer. One example of the electron transport binder materials is polyvinyl carbazole.

In the fourth embodiment, the organic light-emitting layer 8 may be produced by a wet process using another hole transport material or the like, another layer configuration, or another coating solution, as is the case with the first embodiment. At least one of the electron transport binder, hole transport material and light-emitting dopant in the light-emitting layer 8 preferably has a molecular structure not point-symmetric. Particularly preferably, at least two of them have a molecular structure not point-symmetric.

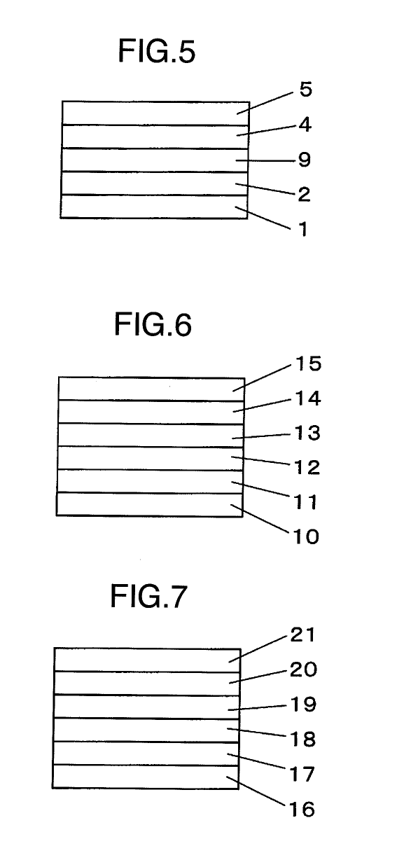

FIG. 5 illustrates the fifth embodiment of organic light-emitting display device of the present invention. In this embodiment, an organic light-emitting layer 9 is characterized in that it contains a binder, hole/electron transport material and light-emitting dopant. The hole/electron transport material means that it has a function of transferring both holes and electrons. Of hole transport/electron transport materials, those having a molecular structure not point-symmetric are suitably used for their capability of preventing crystallization of the light-emitting layer. More specifically, the hole transport/electron transport materials having a molecular structure represented by the following general formula are particularly preferable, wherein, M and O are each an aryl group which may be substituted, and N is a coupling group or mere bond which couples M and O with each other.

M-N-O (formula 19)

In the fifth embodiment, the organic light-emitting layer 9 may be produced by a wet process using another binder material or the like, another layer configuration, or another coating solution, as is the case with the first embodiment. At least one of the binder, hole/electron transport material and light-emitting dopant in the light-emitting layer 9 preferably has a molecular structure not point-symmetric. More preferably, at least two of them have a molecular structure not point-symmetric.

The organic light-emitting layer in each of the above embodiments shown at FIG. 1 to 5 may contain a surfactant, as required. It may be selected from various ones. Examples of useful surfactants include siloxane- and fluorine-base ones, and nonionic ones. Incorporation of a surfactant improves flatness of the organic light-emitting layer, thereby decreasing wattless current to improve power efficiency.

The organic light-emitting display device produced in each of the above embodiments shown at FIGS. 1 to 5 is of so-called bottom emission type. However, the present invention is not limited to this type, and can have a so-called top emission type structure. The top emission type structures are illustrated in FIGS. 6 and 7 as the respective sixth and seventh embodiments.

The organic light-emitting display device illustrated in FIG. 6 has a structure with a lower electrode 10 as a light-reflecting layer which supports a hole-injecting layer 11, organic light-emitting layer 12, electron transport layer 13, buffer layer 14 and upper electrode 15 as a transparent electrode. The lower electrode 10 may have a laminated structure with a highly light-reflecting metal (e.g., Al or Ag) and electroconductive oxide (e.g., ITO or IZO). Moreover, a metal of high reflectivity and high work function, e.g., Cr, may be used by itself.

The buffer layer 14 may be of an oxide (e.g., V₂O₅ or MoO₃) or organic material codeposited with a doping material. The transparent upper electrode 15 may be of a transparent material, e.g., IZO or ITO. Moreover, Ag or Cr, which functions even when it is thin and has a high transmittance, may be also used. The other layers including the hole-injecting layer 11 may have structures similar to those of the device in the first embodiment.

The organic light-emitting display device illustrated in FIG. 7 has a structure with a lower electrode 16 as a light-reflecting layer which supports an electron transport layer 17, organic light-emitting layer 19, buffer layer 20 and upper electrode 21 as a transparent electrode. The hole transport layer 19 may be of 4,4′-bis[N-(1-naphthyl)-N-phenylamino]bisphenyl. The other layers including the electron transport layer 17 may have structures similar to those of the device in the first or sixth embodiment.

### EXAMPLES

Next, the present invention is described in more detail by Examples and Comparative Examples, which by no means limit the present invention.

### Example 1

An organic light-emitting display device having a structure illustrated in FIG. 1 was produced as the one corresponding to a pixel emitting red light, wherein the lower electrode 10 was of ITO, hole-injecting layer was of poly(3,4-ethylenedioxythiophene) (PEDOT) and polystyrene sulfonate (PSS), binder in the organic light-emitting layer was of polycarbonate having the molecular structure [b-1], hole transport layer 11 was of triphenylamine derivative having the molecular structure [h-1], electron transport layer was of carbazole derivative having the molecular structure [e-1] and light-emitting dopant was of Ir complex having the molecular structure [d-1]. The ratio of these materials was set at 50/20/25/5 by mass. Each of these materials was dissolved in a mixed polar solvent selected from aromatic compounds, alcohols and so forth to produce a coating solution. The solid content in the solution was set at 0.5% by mass. It had a viscosity of 1 to 20 mPa·s. Then, the organic light-emitting layer was formed by ink jetting using these coating solutions. Then, the electron transport layer of bis(2-methyl-8-quinolinolato)-4-(phenylphenolato) aluminum (BAlq) was formed by vacuum deposition. Then, the upper electrode of a laminate of LiF and Al was formed. This produced the objective organic light-emitting display device. It had the uniformly formed light-emitting layer and exhibited a high power efficiency.

### Comparative Example 1

An organic light-emitting display device was produced in the same manner as in Example 1, except that the organic light-emitting layer was produced using a coating solution of polyvinyl carbazole and Ir complex having the molecular structure [d-1], and its power efficiency was measured. It was found that the organic light-emitting display device produced in Example 1 had a 1.2 times higher power efficiency than the one produced in Comparative Example 1. Superiority of the device produced in Example 1 is conceivably attributable to its structure which improves uniformity of the light-emitting layer, reduces wattless current and improves transferability of the light-emitting layer.

### Example 2

An organic light-emitting display device having a structure illustrated in FIG. 3 was produced as the one corresponding to a pixel emitting red light. More specifically, it was produced as an objective device in the same manner as in Example 1, except that the organic light-emitting layer was produced using coating solutions each containing the hole transport binder having the molecular structure [b-2], electron transport material having the molecular structure [e-1] or light-emitting dopant having the molecular structure [d-1]. It had a 1.2 times higher power efficiency than the one produced in Comparative Example 1.

### Example 3

An organic light-emitting display device having a structure illustrated in FIG. 4 was produced as the one corresponding to a pixel emitting red light. More specifically, it was produced as an objective device in the same manner as in Example 1, except that the organic light-emitting layer was produced using coating solutions each containing polyvinyl carbazole as the electron transport binder, the hole transport material having the molecular structure [h-1] or light-emitting dopant having the molecular structure [d-1]. It had a 1.2 times higher power efficiency than the one produced in Comparative Example 1.

### Example 4

An organic light-emitting display device having a structure illustrated in FIG. 2 was produced as the one corresponding to a pixel emitting red light. More specifically, it was produced as an objective device in the same manner as in Example 1, except that the electron-injecting layer placed between the electron transport layer and upper electrode was of the electron transport material having the molecular structure [e-2] codeposited with Cs, and the upper electrode was of Al. It had a 1.5 times higher power efficiency than the one produced in Comparative Example 1.

### Example 5 and Comparative Example 2

An organic light-emitting display device for emitting red light was produced in Example 5 in the same manner as in Example 1, except that the light-emitting dopant having the molecular structure [d-1] for the organic light-emitting layer was replaced by the one having the molecular structure [d-2], which is not point-symmetric. An organic light-emitting display device for emitting red light was produced in Comparative Example 2 in the same manner as in Comparative Example 1, except that the light-emitting dopant having the molecular structure [d-1] for the organic light-emitting layer was replaced by the one having the structure [d-2]. These devices were measured for power efficiency. The device produced in Example 5 had a 1.3 times higher power efficiency than the one produced in Comparative Example 2.

### Example 6

An organic light-emitting display device for emitting red light was produced in the same manner as in Example 2, except that the light-emitting dopant having the molecular structure [d-1] for the organic light-emitting layer was replaced by the one having the molecular structure [d-2], which is not point-symmetric. It had a 1.3 times higher power efficiency than the one produced in Comparative Example 2.

### Example 7

An organic light-emitting display device for emitting red light was produced in the same manner as in Example 3, except that the light-emitting dopant having the molecular structure [d-1] for the organic light-emitting layer was replaced by the one having the molecular structure [d-2], which is not point-symmetric. It had a 1.3 times higher power efficiency than the one produced in Comparative Example 2.

### Examples 8 to 10

Organic light-emitting display devices for emitting red light were produced in Examples 8 to 10 in the same manner as in respective Examples 1 to 3, except that the coating solution was incorporated with a siloxane-base surfactant. These devices had a respective 1.3, 1.3 and 1.25 times higher power efficiency than the one produced in Comparative Example 1.

### Examples 11 and 12

Organic light-emitting display devices for emitting red light were produced in Examples 11 and 12 in the same manner as in respective Examples 5 and 7, except that the hole transport material having the molecular structure [h-1] for the organic light-emitting layers was replaced by the one having the molecular structure [h-2]. Each of the devices had a 1.4 times higher power efficiency than the one produced in Comparative Example 2.

### Examples 13 and 14

Organic light-emitting display devices for emitting red light were produced in Examples 13 and 14 in the same manner as in respective Examples 5 and 7, except that the hole transport material having the molecular structure [h-1] for the organic light-emitting layers was replaced by the one having the molecular structure [h-3]. Each of the devices had a 1.5 times higher power efficiency than the one produced in Comparative Example 2.

### Examples 15 and 16

Organic light-emitting display devices for emitting red light were produced in Examples 15 and 16 in the same manner as in respective Examples 5 and 6, except that the electron transport material having the molecular structure [e-1] for the organic light-emitting layers was replaced by the one having the molecular structure [e-2]. Each of the devices had a 1.4 times higher power efficiency than the one produced in Comparative Example 2.

### Example 17

An organic light-emitting display device for emitting red light was produced in the same manner as in respective Example 6, except that the organic light emitting layer was composed of the electron transport material having the molecular structure [e-3] and light-emitting dopant having the molecular structure [d-2]. It had a 1.2 times higher power efficiency than the one produced in Comparative Example 2.

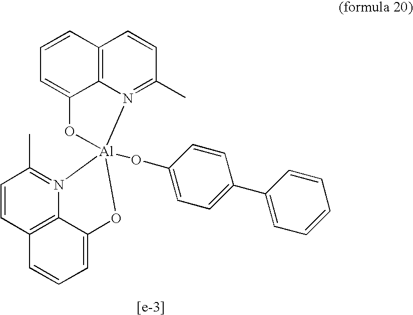

For the electron transport layer, other compounds having a molecular structure not point-symmetric can be used in place of the compound having the molecular structure [e-3]. These compounds include quinolinol derivatives, carbazole derivatives, oxadiazole derivatives, oxathiazole derivatives, benzimidazole derivatives, triazole derivatives, fullerene derivatives, phenanthroline derivatives and quinoline derivatives. They may be used either individually or in combination of the two or more compounds.

Moreover, the coating solution for the organic light-emitting layer may contain a surfactant, e.g., siloxane-base one, as used in Example 8.

### Example 18

An organic light-emitting display device for emitting red light was produced in the same manner as in respective Example 7, except that the organic light-emitting layer was composed of the hole transport layer of the compound having the molecular structure [h-2] and light-emitting dopant of the compound having the molecular structure [d-2]. It had a 1.2 times higher power efficiency than the one produced in Comparative Example 2. The hole transport material is not limited to the compound having the molecular structure [h-2], but may be selected from triphenylamine derivatives, star-burst amine-base compounds, stilbene derivatives, hydrazone derivatives, thiophene derivatives and metallic complexes, e.g., Ir and Os complexes. They may be used either individually or in combination.

Moreover, the coating solution for the organic light-emitting layer may contain a surfactant, e.g., siloxane-base one, as used in Example 8.

### Example 19

An organic light-emitting display device for emitting red light was produced in the same manner as in respective Example 11, except that the organic light-emitting layer was composed of the hole transport layer of the compound having the molecular structure [h-2], electron transport layer of the compound having the molecular structure [e-1] and light emitting layer of the compound having the molecular structure [d-2]. It had a 1.3 times higher power efficiency than the one produced in Comparative Example 2.

The hole transport material is not limited to the compound having the molecular structure [h-2], but may be selected from triphenylamine derivatives, star-burst amine-base compounds, stilbene derivatives, hydrazone derivatives, thiophene derivatives and metallic complexes, e.g., Ir and Os complexes.

The electron transport material is not limited to the compound having the molecular structure [e-1], but may be selected from carbazole derivatives, quinolinol derivatives, oxadiazole derivatives, oxathiazole derivatives, triazole derivatives, fullerene derivatives, phenanthroline derivatives and quinoline derivatives, which are not point-symmetric.

These hole transport materials may be used either individually or in combination, and so are the electron transport materials.

Moreover, the coating solution for the organic light-emitting layer may contain a surfactant, e.g., siloxane-base one, as used in Example 8.

### Example 20

An organic light-emitting display device for emitting red light was produced in the same manner as in Example 19, except that the organic light-emitting layer was composed of the electron transport layer of the compound having the molecular structure [e-3], hole transport layer of the compound having the molecular structure [h-4] and light emitting layer of the compound having the molecular structure [d-2]. It had a 1.3 times higher power efficiency than the one produced in Comparative Example 2.

The hole transport material is not limited to the compound having the molecular structure [h-4], but may be selected from triphenylamine derivatives, star-burst amine-base compounds, stilbene derivatives, hydrazone derivatives, thiophene derivatives and metallic complexes, e.g., Ir and Os complexes.

The hole transport materials may be used either individually or in combination, and so are the electron transport materials.

Moreover, the coating solution for the organic light-emitting layer may contain a surfactant, e.g., siloxane-base one, as used in Example 8.

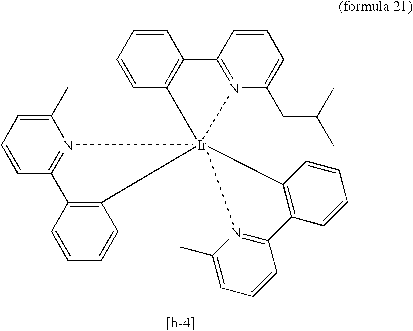

### INDUSTRIAL APPLICABILITY

The organic light-emitting display device of the present invention can go into displays for TV sets, various information terminals and so forth, because it is highly efficient and can be simply produced.

It should be further understood by those skilled in the art that although the foregoing description has been made on embodiments of the invention, the invention is not limited thereto and various changes and modifications may be made without departing from the spirit of the invention and the scope of the appended claims.

### ADVANTAGES OF THE INVENTION

The present invention can provide a light-emitting layer uniformly dispersed with a light-emitting dopant. This enables to produce an organic light-emitting display device of high efficiency and long serviceability by a simple wet process.

1. An organic light-emitting display device comprising:
an upper electrode;
a lower electrode; and
an organic light-emitting layer placed between the upper electrode and the lower electrode,
wherein one of the upper and lower electrodes is a transparent electrode and the other is a light-reflecting electrode, and
wherein the organic light-emitting layer contains at least one of a hole transport material and an electron transport material and contains a light-emitting dopant.

2. The organic light-emitting display device according to claim 1, wherein the organic light-emitting layer contains the hole transport material and the electron transport material, and each of the hole transport material, the electron transport material and the light-emitting dopant in the organic light-emitting layer has a molecular structure not point-symmetric.

3. The organic light-emitting display device according to claim 1, wherein the organic light-emitting layer contains the electron transport material, and each of the electron transport material and the light-emitting dopant in the organic light-emitting layer has a molecular structure not point-symmetric.

4. The organic light-emitting display device according to claim 1, wherein the organic light-emitting layer contains the hole transport material, and each of the hole transport material and the light-emitting dopant in the organic light-emitting layer has a molecular structure not point-symmetric.

5. The organic light-emitting display device according to claim 1, wherein the organic light-emitting layer contains a binder, the hole transport material, the electron transport material and the light-emitting dopant.

6. The organic light-emitting display device according to claim 1, wherein the organic light-emitting layer contains a hole transport binder, the electron transport material and the light-emitting dopant.

7. The organic light-emitting display device according to claim 1, wherein the organic light-emitting layer contains an electron transport binder, the hole transport material and the light-emitting dopant.

8. The organic light-emitting display device according to claim 1, wherein the organic light-emitting layer contains a binder, a hole/electron transport material and the light-emitting dopant.

9. The organic light-emitting display device according to claim 1 further comprising an organic layer in contact with the upper electrode or the lower electrode, wherein the organic layer contains a dopant capable of ionizing a material present in the organic layer.

10. The organic light-emitting display device according to claim 5, wherein at least one of the binder, the hole transport material, the electron transport material and the light-emitting dopant has a molecular structure not point-symmetric.

11. The organic light-emitting display device according to claim 6, wherein at least one of the hole transport binder, the electron transport material and the light-emitting dopant has a molecular structure not point-symmetric.

12. The organic light-emitting display device according to claim 7, wherein at least one of the electron transport binder, the hole transport material and the light-emitting dopant has a molecular structure not point-symmetric.

13. The organic light-emitting display device according to claim 8, wherein at least one of the binder, the hole/electron transport material and the light-emitting dopant has a molecular structure not point-symmetric.

14. The organic light-emitting display device according to claim 10, wherein the light-emitting dopant is a metallic complex having at least two species of ligands.

15. The organic light-emitting display device according to claim 11, wherein the light-emitting dopant is a metallic complex having at least two species of ligands.

16. The organic light-emitting display device according to claim 12, wherein the light-emitting dopant is a metallic complex having at least two species of ligands.

17. The organic light-emitting display device according to claim 13, wherein the light-emitting dopant is a metallic complex having at least two species of ligands.

18. The organic light-emitting display device according to claim 10, wherein the hole transport material has a structure represented by the following general formula:
A-B-C (formula 1)
(wherein, A and C are each an aryl group which can be substituted, and B is a coupling group or mere bond which couples A and C with each other),
or by the following general formula: 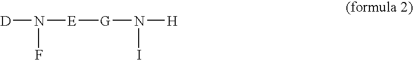
(wherein, D, E, F, G, H and I are each an aryl group which can be substituted, and at least one of D, E and F is not the same as the another and at least one of G, H and I is not the same as the another).

19. The organic light-emitting display device according to claim 12, wherein the hole transport material has a structure represented by the following general formula:
A-B-C (formula 1)
(wherein, A and C are each an aryl group which can be substituted, and B is a coupling group or mere bond which couples A and C with each other),
or by the following general formula: 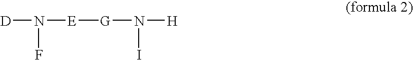
(wherein, D, E, F, G, H and I are each an aryl group which can be substituted, and at least one of D, E and F is not the same as the another and at least one of G, H and I is not the same as the another).

20. The organic light-emitting display device according claim 10, wherein the electron transport material has a structure represented by the following general formula:
J-K-L (formula 3)
(wherein, J and L are each an aryl group which can be substituted, and K is a coupling group or mere bond which couples J and L with each other),
or by the following general formula:
M-N-O (formula 4)
(wherein, M and O are each an aryl group which can be substituted, and N is a coupling group or mere bond which couples J and L with each other).

21. The organic light-emitting display device according claim 11, wherein the electron transport material has a structure represented by the following general formula:
J-K-L (formula 3)
(wherein, J and L are each an aryl group which can be substituted, and K is a coupling group or mere bond which couples J and L with each other),
or by the following general formula:
M-N-O (formula 4)
(wherein, M and O are each an aryl group which can be substituted, and N is a coupling group or mere bond which couples J and L with each other).

22. The organic light-emitting display device according to claim 1, wherein the organic light-emitting layer contains a surfactant.

23. The organic light-emitting display device according to claim 1, wherein the organic light-emitting layer contains the hole transport material and the electron transport material.

24. A coating solution for producing an organic light-emitting layer in an organic light-emitting display device, wherein the organic light-emitting layer is placed between an upper electrode and a lower electrode in the device and the coating solution contains a binder, at least one of a hole transport material and an electron transport material, and a light-emitting dopant and a solvent.

25. The coating solution for producing an organic light-emitting layer according to claim 24, wherein the coating solution contains a hole transport binder, the electron transport material, the light-emitting dopant and the solvent.

26. The coating solution for producing an organic light-emitting layer according to claim 24, wherein the coating solution contains an electron transport binder, the hole transport material, the light-emitting dopant and the solvent.

27. The coating solution for producing an organic light-emitting layer according to claim 24, wherein the coating solution contains the binder, a hole/electron transport material, the light-emitting dopant and the solvent.

28. The coating solution for producing an organic light-emitting layer according to claim 24, further comprising a surfactant.
